(19) United States
(12) Patent Application Publication
(10) Pub. No.: US 2021/0389882 A1
(43) Pub. Date: Dec. 16, 2021

(54) STORAGE DEVICE AND LOW-LEVEL FORMATTING METHOD THEREFOR

(71) Applicant: RayMX Microelectronics Corp., Hefei (CN)

(72) Inventors: Yufeng Zhou, Jiangsu Province (CN); SHUANGXI CHEN, Jiangsu Province (CN)

(21) Appl. No.: 17/107,983

(22) Filed: Dec. 1, 2020

(30) Foreign Application Priority Data
Jun. 12, 2020 (CN) 202010536531.8

(51) Int. Cl. G06F 3/06

(52) U.S. Cl. CPC G06F 3/0619; G06F 3/064; G06F 3/0673; G06F 3/0653; G06F 3/0659; G06F 3/0652

(57) ABSTRACT

Disclosed is a storage device and a low-level formatting method therefor. The low-level formatting method includes: searching whether an RDT result or firmware storage information is stored in storage blocks of the storage device; determining whether a number of P/E cycles and a TBW of the storage device are recorded in a P/E cycle record and a TBW record included in at least one of the RDT result and the firmware storage information if at least one of the RDT result and the firmware storage information is stored; setting values of the P/E cycles and the TBW to zero if the RDT result and the firmware storage information are not stored or the P/E cycles and the TBW are not recorded in the P/E cycle record and the TBW record.

### CROSS REFERENCE TO RELATED APPLICATION

This application claims the priority benefit of Chinese Patent Application Serial Number 202010536531.8, filed on Jun. 12, 2020, the full disclosure of which is incorporated herein by reference.

### BACKGROUND

### Technical Field

The invention relates to a storage device and a low-level formatting method therefor, and more particularly to a flash memory device and a low-level formatting method therefor.

### Related Art

A solid state disk (SSD) is a hard disk made of an array of solid electronic storage chips. The number of program-erase (P/E) cycles of the SSD refers to the number of erasing and writing times of the storage medium (that is, NAND flash) in the SSD, while the terabytes written (TBW) refers to the number of terabytes written in the lifetime of the SSD. Both of the two parameters are indicators for measuring the lifetime of the SSD.

FIG. 1 is a schematic diagram that a conventional whole system firmware 11 in the SSD reads a configuration file (config) from a storage block 131. First, before low-level format of the SSD, the low-level formatting firmware 12 writes an internal configuration file into the storage block 131 of the NAND flash 13, and then the whole system firmware 11 reads the configuration file from the storage block 131, wherein the configuration file contains a lot of parameter information, such as a low-level format mode. From the parameter information, it can be determined to perform low-level format on the reliability and duration test (RDT) firmware 14 as shown in FIG. 2 or the whole system firmware 11 as shown in FIG. 3.

FIG. 2 is a schematic diagram of performing low-level format on the conventional RDT firmware 14. Referring to FIG. 2 and FIG. 4, the RDT firmware 14 reads the configuration file from the storage block 131 and obtains the information of performing low-level format on the RDT firmware 14 (step S41), so the RDT firmware 14 starts to test the storage blocks 131 in the NAND flash 13 one by one (step S42), and the test results are written back to one of the storage blocks 131 of the NAND flash 13 (step S43).

FIG. 3 is a schematic diagram of performing low-level format on the conventional whole system firmware 11. In this mode, as shown in FIG. 5, the whole system firmware 11 reads the configuration file from the storage block 131, and obtains the information of performing low-level format on the whole system firmware 11 (step S51). Then, the whole system firmware 11 executes the read operation of the master controller (step S52a), the write operation of the master controller (step S52b), the garbage collection operation (step S52c), and so on. In this mode, the information read by the whole system firmware 11 resides in the SRAM, and the whole system firmware 11 can modify (update) the content of the information at any time, and write information of the number of P/E cycles and the TBW into the NAND flash to make a backup at regular intervals.

FIG. 6 is a flowchart of the conventional low-level formatting method. The conventional low-level formatting method comprises the following steps of: determining to perform low-level format on the conventional RDT firmware 14 (that is, performing the mode of FIG. 2) or the conventional whole system firmware 11 (that is, performing the mode of FIG. 3) (step S61), checking the damaged blocks of the NAND flash (step S62), calibrating the data to select the pulse phase (step S63), updating the relevant parameters, such as the damaged blocks and the selected pulse phase, to the firmware, and writing the updated firmware to the NAND flash (step S64).

In addition, before the SSD is shipped, the low-level format mode of FIG. 2 is performed on the RDT firmware, and then the low-level format mode of FIG. 3 is performed on the whole system firmware. However, in the test process of the RDT firmware in FIG. 2, performing read and write operations is needed to test blocks, so the originally written data is destroyed (that is, the double strikethrough as shown in FIG. 2). Therefore, the information of the number of P/E cycles and the TBW disappears. As a result, for the SSD under a return merchandise authorization (RMA), it is not possible to inherit the previous information of the number of P/E cycles and the TBW of the SSD after the low-level formatting method is performed on the SSD again.

Furthermore, if the SSD has been used for a long time, the number of P/E cycles and the TBW of the SSD are accumulated to the considerable values; after the low-level formatting method is performed on the SSD again due to some factors (that is, in the test process of the RDT firmware in FIG. 2), the information of the number of P/E cycles and the TBW is deleted. Therefore, the lifetime of the SSD that the user know is not the true lifetime of the SSD. As a result, the user can not back up the data before the end of the true lifetime of the SSD, resulting in irreparable data loss.

### SUMMARY

In view of the above, how to inherit the previous information of the number of P/E cycles and the TBW of the SSD to make the user can obtain the true number of P/E cycles and the true TBW of the SSD and avoid data loss after the low-level formatting method is performed again, becomes a problem to be solved.

The present disclosure provides a low-level formatting method for a storage device, the storage device has a plurality of storage blocks, and the low-level formatting method comprises: searching whether an RDT result or firmware storage information is stored in the plurality of storage blocks of the storage device, wherein at least one of the RDT result and the firmware storage information comprise a program-erase cycle (P/E cycle) record and a terabyte written (TBW) record of the storage device; determining whether a number of P/E cycles and a TBW of the storage device are recorded in the P/E cycle record and the TBW record if at least one of the RDT result and the firmware storage information is stored in the plurality of storage blocks of the storage device; setting values of P/E cycles and the TBW of the storage device to zero and then writing the values of the P/E cycles and the TBW of the storage device into one of the plurality of storage blocks of the storage device if the RDT result and the firmware storage information are not stored in the plurality of storage blocks of the storage device; writing values of the recorded number of P/E cycles and the recorded TBW of the storage device into one of the plurality of storage blocks of the storage device if the P/E cycles and the TBW of the storage device are recorded in the P/E cycle record and the TBW record.

The present disclosure also provides a storage device. The storage device comprises a processor and a plurality of storage blocks, wherein the processor executes the low-level formatting method.

According to an embodiment of the present disclosure, the low-level formatting method for the storage device further comprises: setting the values of the P/E cycles and the TBW of the storage device to zero and then writing the values of the P/E cycles and the TBW of the storage device into one of the plurality of storage blocks of the storage device if the P/E cycles and the TBW of the storage device are not recorded in the P/E cycle record and the TBW record.

According to an embodiment of the present disclosure, the low-level formatting method for the storage device further comprises: confirming the validity of the P/E cycle record and the TBW record.

According to an embodiment of the present disclosure, the low-level formatting method for the storage device further comprises: reading one of the plurality of storage blocks of the storage device; obtaining the P/E cycle record and the TBW record from the one of the plurality of storage blocks of the storage device; and integrating the obtained P/E cycle record and the obtained TBW record into the RDT result.

According to an embodiment of the present disclosure, the P/E cycle record and the TBW record of the storage device at different time points are stored in the plurality of storage blocks of the storage device, and the low-level formatting method further comprises: reading one of the plurality of storage blocks of the storage device; obtaining the P/E cycle record and the TBW record of the storage device at the latest time point; and writing the obtained P/E cycle record and the obtained TBW record back to a predetermined storage block of the plurality of storage blocks of the storage device to generate the firmware storage information.

According to an embodiment of the present disclosure, the storage device is a flash memory device.

According to an embodiment of the present disclosure, in the process of obtaining and writing the P/E cycle record and the TBW record, the low-level formatting method further comprises: integrating test results of the plurality of storage blocks, the P/E cycle record, and the TBW record into the RDT result.

According to an embodiment of the present disclosure, in the process of obtaining and writing the P/E cycle record and the TBW record at the latest time point of the storage device, the low-level formatting method for the storage device further comprises: executing a read operation; executing a write operation; and executing a garbage collection operation.

Other advantages of the present disclosure are explained in more detail with the following description and drawings.

It should be understood, however, that this summary may not contain all aspects and embodiments of the present disclosure, that this summary is not meant to be limiting or restrictive in any manner, and that the invention as disclosed herein will be understood by one of ordinary skill in the art to encompass obvious improvements and modifications thereto.

### BRIEF DESCRIPTION OF THE DRAWINGS

The features of the exemplary embodiments believed to be novel and the elements and/or the steps characteristic of the exemplary embodiments are set forth with particularity in the appended claims. The Figures are for illustration purposes only and are not drawn to scale. The exemplary embodiments, both as to organization and method of operation, may best be understood by reference to the detailed description which follows taken in conjunction with the accompanying drawings in which:

FIG. 1 is a schematic diagram of a whole system firmware (WSF) of a conventional SSD reading a configuration file.

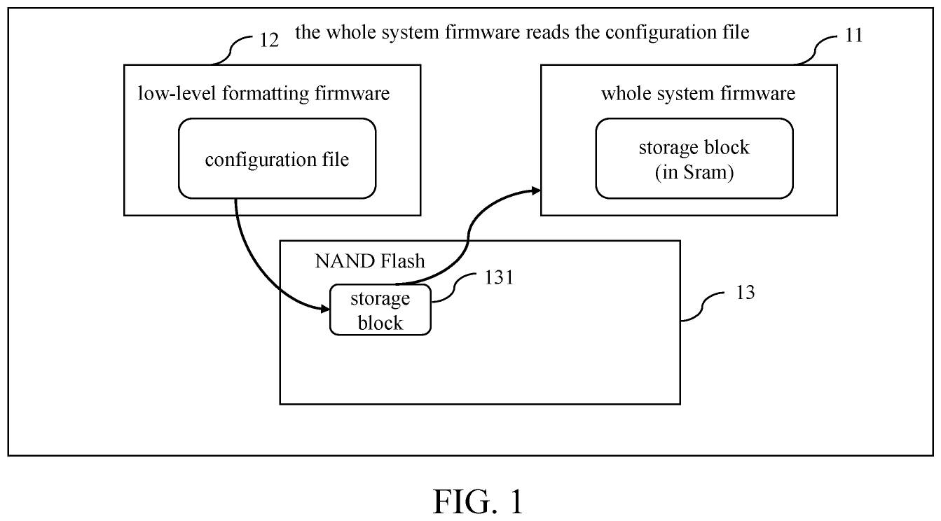

FIG. 2 is a schematic diagram of performing low-level format on a conventional RDT firmware of a SSD.

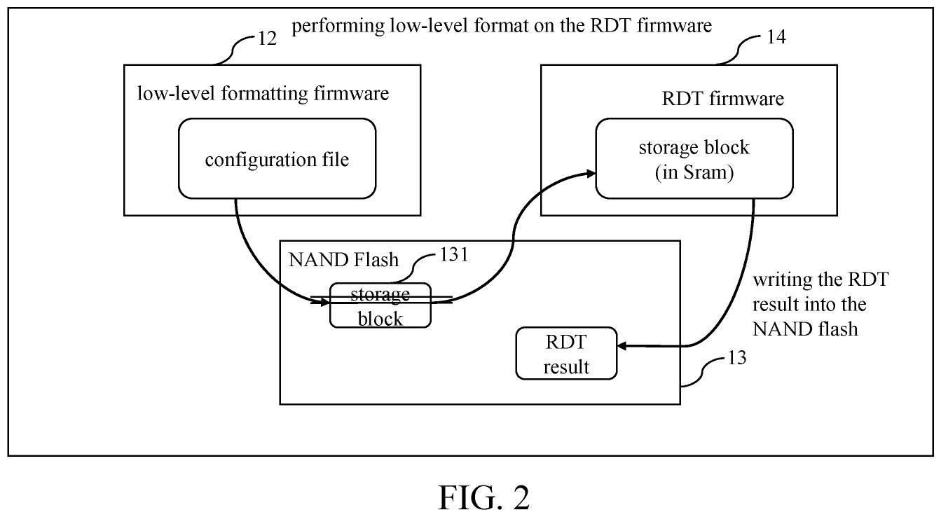

FIG. 3 is a schematic diagram of performing low-level format on a conventional whole system firmware of a SSD.

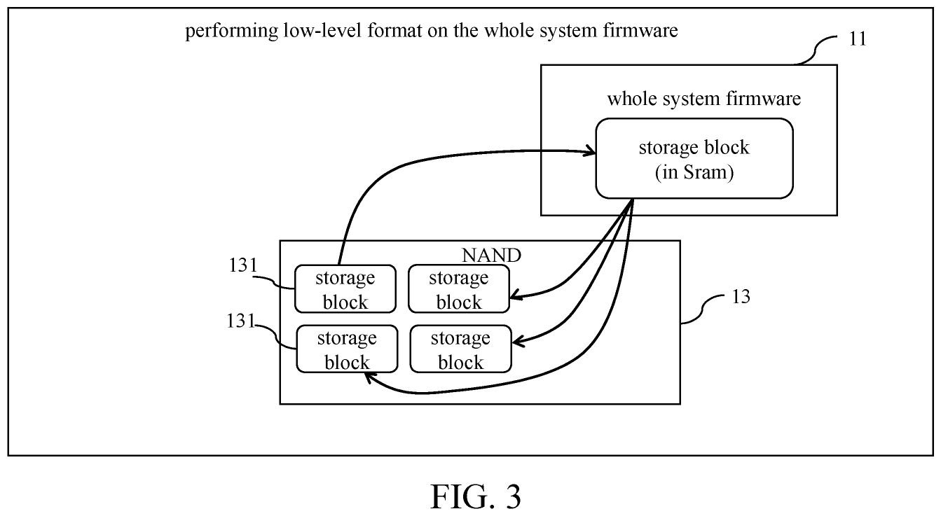

FIG. 4 is a flowchart of performing low-level format on a conventional RDT firmware of a SSD.

FIG. 5 is a flowchart of performing low-level format on a conventional whole system firmware of a SSD.

FIG. 6 is a flow chart of a conventional low-level formatting method for a SSD.

FIG. 7 is a flowchart of a low-level formatting method for a storage device according to an embodiment of the present disclosure.

FIG. 8 is a flowchart of a whole system firmware generating firmware storage information in a low-level formatting method for a storage device according to an embodiment of the present disclosure.

FIG. 9 is a flowchart combing the process of the whole system firmware generating the firmware storage information and the process of performing low-level format on the conventional whole system firmware in a low-level formatting method for a storage device according to an embodiment of the present disclosure.

FIG. 10 is a flowchart of an RDT firmware generating an RDT result in a low-level formatting method for a storage device according to an embodiment of the present disclosure.

FIG. 11 is a flowchart combing the process of the RDT firmware generating the RDT result and the process of performing low-level format on the conventional RDT firmware in a low-level formatting method for a storage device according to an embodiment of the present disclosure.

### DETAILED DESCRIPTION OF THE EMBODIMENTS

The present disclosure will now be described more fully hereinafter with reference to the accompanying drawings, in which exemplary embodiments of the invention are shown. This present disclosure may, however, be embodied in many different forms and should not be construed as limited to the embodiments set forth herein. Rather, these embodiments are provided so that this present disclosure will be thorough and complete, and will fully convey the scope of the present disclosure to those skilled in the art.

Certain terms are used throughout the description and following claims to refer to particular components. As one skilled in the art will appreciate, manufacturers may refer to a component by different names. This document does not intend to distinguish between components that differ in name but function. It will be understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having the same name (but for use of the ordinal term) to distinguish the claim elements.

It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent.” etc.)

The following description is of the best-contemplated mode of carrying out the invention. This description is made for the purpose of illustration of the general principles of the invention and should not be taken in a limiting sense. The scope of the invention is best determined by reference to the appended claims.

In the following embodiment, the same reference numerals are used to refer to the same or similar elements throughout the invention.

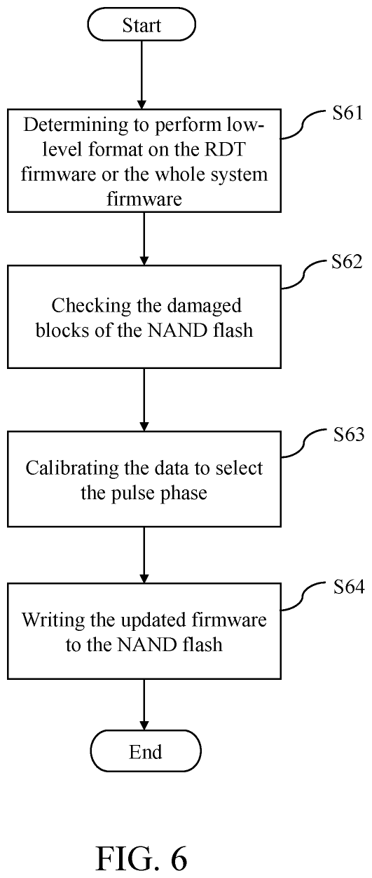

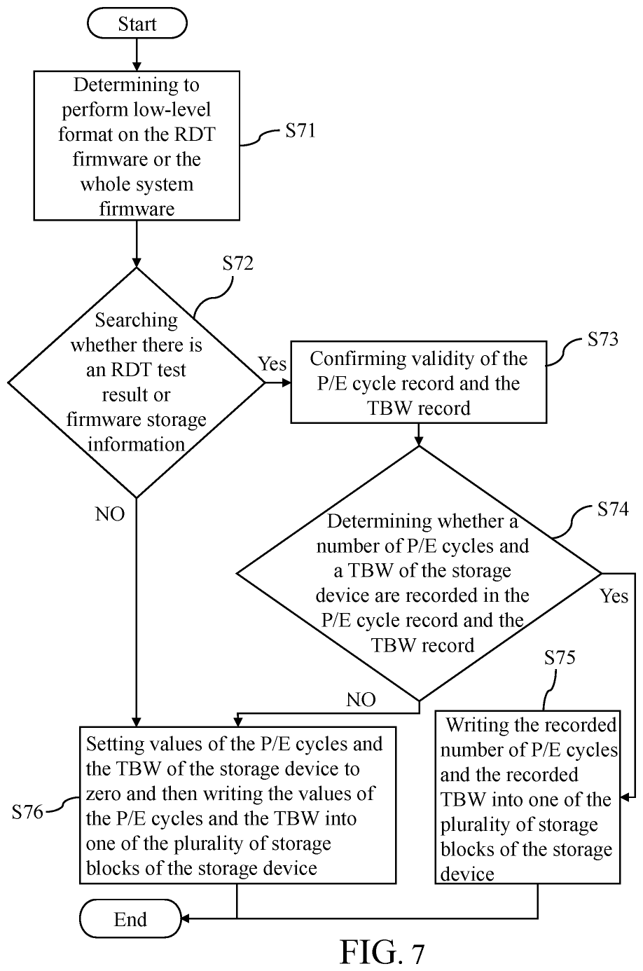

FIG. 7 is a flowchart that information of the number of P/E cycles and the TBW can be retained in a low-level formatting method for a storage device according to an embodiment of the present disclosure. FIG. 7 is a flowchart of performing low-level format on the RDT firmware or the whole system firmware according to an embodiment of the present disclosure. It is modified from the conventional process of FIG. 6. Step S71 in the embodiment of the present disclosure is the same as step S61 in FIG. 6, and both are to determine that the low-level format is performed on the RDT firmware or the whole system firmware. Next, in step S72, the storage blocks of the NAND flash of the SSD are searched to determine whether there is an RDT result (that is, a pre-RDT result) or firmware storage information (that is, a pre-WS sblock), wherein the RDT result and the firmware storage information may include a P/E Cycle record and a TBW record of the storage device. The RDT result is a record generated after the RDT for the SSD is finished. If the RDT result is stored in the storage blocks of the NAND flash of the SSD, it means that the SSD has just been manufactured and the RDT for the SSD has been completed, and the SSD has not been used. If the firmware storage information is stored in the storage blocks of the NAND flash of the SSD, it means that the SSD has a usage record, and the firmware storage information refers to the information stored in the SSD that is returned by the user or sent for repair due to quality problems or other factors after the user uses the SSD. In other words, for the SSD in use, the whole system firmware writes the latest values of the number of P/E cycles and the TBW into the storage block at regular intervals to generate the firmware storage information. By regularly updating the above parameter values, after the SSD is powered off and re-powered, the latest parameter values of the SSD can be obtained from the storage block that records the latest values of the number of P/E cycles and the TBW, so that the latest parameter information of the SSD can be inherited.

In step S72, if the RDT result and the firmware storage information are not stored in the storage blocks of the NAND flash of the SSD, it means that the SSD has just been manufactured, the RDT for the SSD has not been performed, and the SSD has not been used. At this time, the process proceeds to step S76, the default values of the P/E Cycles and the TBW of the SSD (each default value is 0) are written into the storage block of the storage device, and then the process ends. It must be noted that after the end of the process in FIG. 7, what is next to be performed is the subsequent steps of the conventional low-level formatting method in FIG. 6, including: checking the damaged blocks of the NAND flash (step S62), calibrating the data to select the pulse phase (that is, calibrating DQS phase) (step S63), updating the relevant parameters, such as the damaged blocks and the selected pulse phase, to the firmware, and writing the updated firmware to the NAND flash (step S64). Since the above-mentioned subsequent steps of the low-level formatting method are not the focus of the present disclosure, the description is omitted.

In step S72, if the RDT result or the firmware storage information already is stored in the storage blocks of the NAND flash, the process proceeds to step S73 to confirm validity of the P/E cycle record and the TBW record. The validity here refers to whether the P/E cycle record and the TBW record can be recognized by the whole system firmware; if not, it means that the version of the whole system firmware is too old and needs to be updated to the version capable of supporting the P/E cycle record and the TBW record. Then, the process proceeds to step S74 to determine whether a number of P/E cycles and a TBW of the storage device are recorded in the P/E cycle record and the TBW record. If the number of P/E cycles and the TBW of the storage device are recorded, the process proceeds to step S75, and the recorded number of P/E cycles and the recorded TBW are written into the storage block of the storage device. If the number of P/E cycles and the TBW of the storage device are not recorded, it means that the SSD has no usage record. Thus, the process proceeds to step S76 to write the default values of the P/E cycles and the TBW of the storage device (each default value is 0) into the storage block of the storage device.

By the low-level formatting method described in the embodiment of the present disclosure, no matter how many times the RDT or the low-level formatting method is performed, the SSD can retain its latest information of the number of P/E cycles and the TBW after the SSD is used. Therefore, the user can know the true lifetime of the SSD, and can back up data and replace the storage device early before the end of the SSD lifetime, to avoid irreversible data loss.

The flowchart executed in FIG. 7 of the present disclosure is mainly to ensure that the information of the number of P/E cycles and the TBW cannot be lost during the process of performing low-level format or the RDT. However, before the process of FIG. 7 is executed, the whole system firmware and the RDT firmware can execute their methods respectively to generate the firmware storage information and the RDT result respectively, as detailed below.

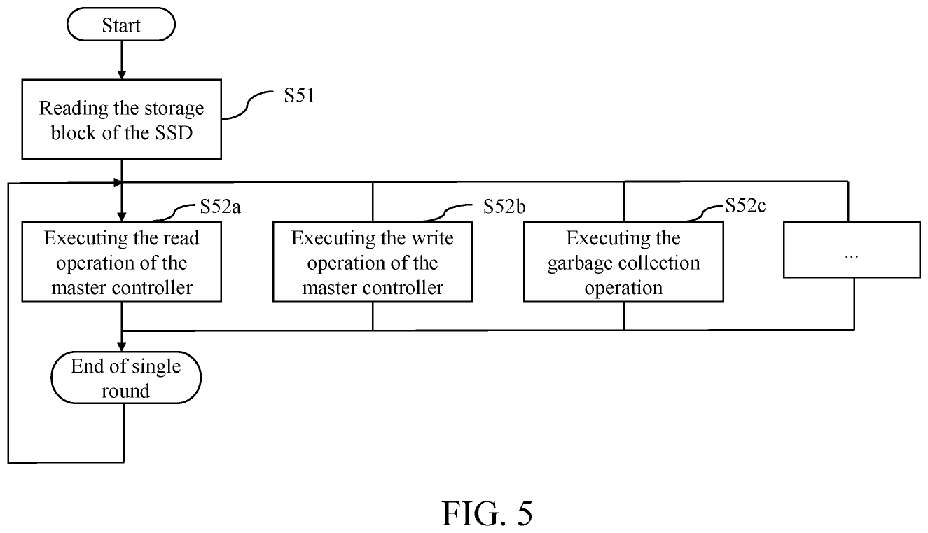

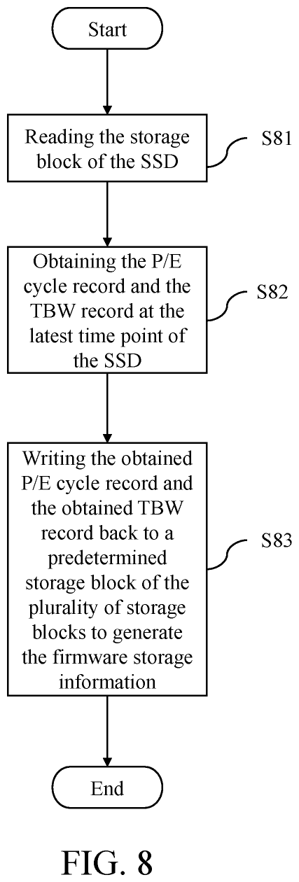

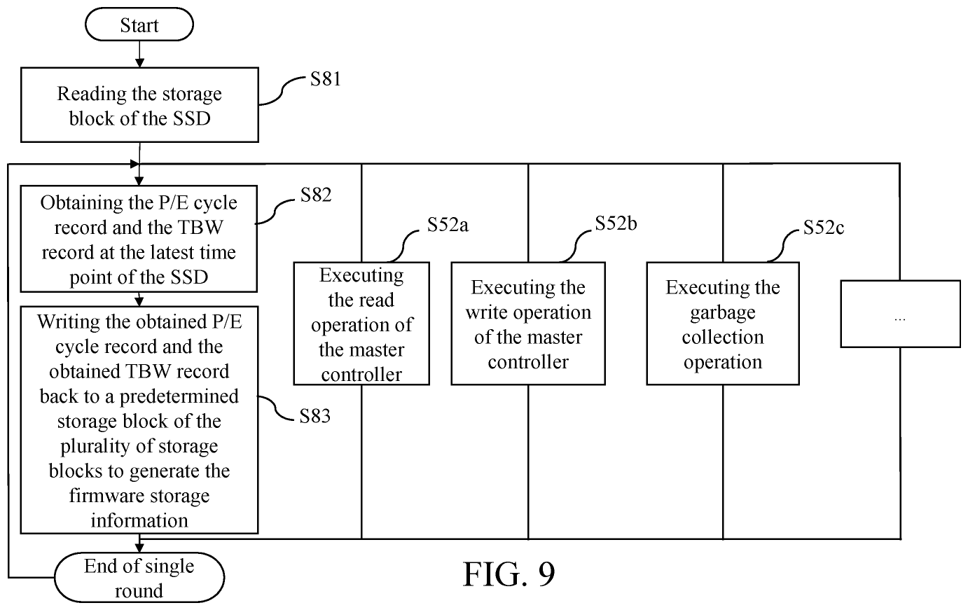

FIG. 8 is a flowchart of the whole system firmware generating the firmware storage information in a low-level formatting method for a storage device according to an embodiment of the present disclosure. As mentioned earlier, when the SSD is in use, the whole system firmware writes the number of P/E cycles, the TBW and other information into different blocks of the NAND flash for backup at regular intervals. Therefore, before the low-level formatting method described in the embodiment of the present disclosure is performed, the whole system firmware first reads the storage block of the SSD (step S81). Then, the whole system firmware obtains the P/E cycle record and the TBW record at the latest time point of the SSD from the storage block (step S82). Finally, the whole system firmware writes the obtained P/E cycle record and the obtained TBW record back to a predetermined storage block of the plurality of storage blocks to generate the firmware storage information (step S83). According to the flowchart in FIG. 8, if performing the low-level formatting method is required later, the whole system firmware can generate the firmware storage information in a situation of performing the low-level format on the whole system firmware, to provide the firmware storage information for the subsequent low-level formatting method (FIG. 7). In addition, the flowchart of FIG. 8 of the present disclosure is modified from the conventional flowchart of FIG. 5, and the details are shown in FIG. 9. That is, the steps S82 and S83 are executed in parallel with the conventional steps of “the read operation of the master controller”, “the write operation of the master controller”, and “the garbage collection operation”. Accordingly, the whole system firmware can simultaneously perform steps S82 and S83 while performing the above conventional steps to generate the firmware storage information at the same time, and then the low-level formatting method of FIG. 7 is used to perform low-level format on the SSD according to the firmware storage information. Therefore, the process of generating the firmware storage information in the embodiment of the present disclosure does not affect the execution of the above conventional steps at all, and therefore does not increase any cost. Without a doubt, it must be noted that the low-level formatting method in FIG. 7 only inherits the information of the number of P/E cycles and the TBW. After the flowchart in FIG. 7 ends, the conventional formatting program is performed (that is, the steps of “checking the damaged blocks of the NAND flash”, “calibrating the data to select the pulse phase”, and “writing the updated firmware to the NAND flash” in FIG. 6), so that the entire low-level formatting process of the SSD is completed.

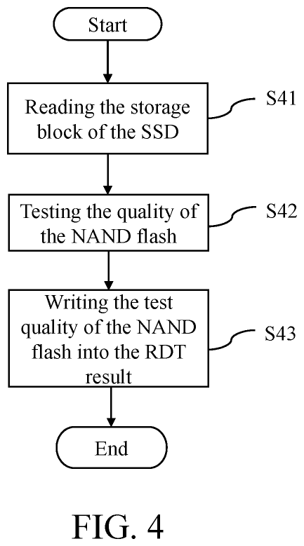

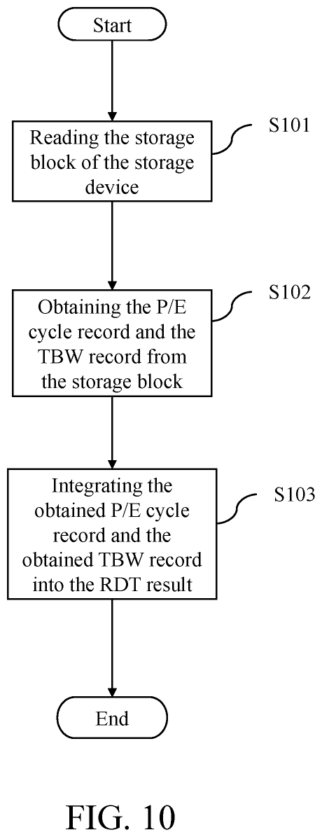

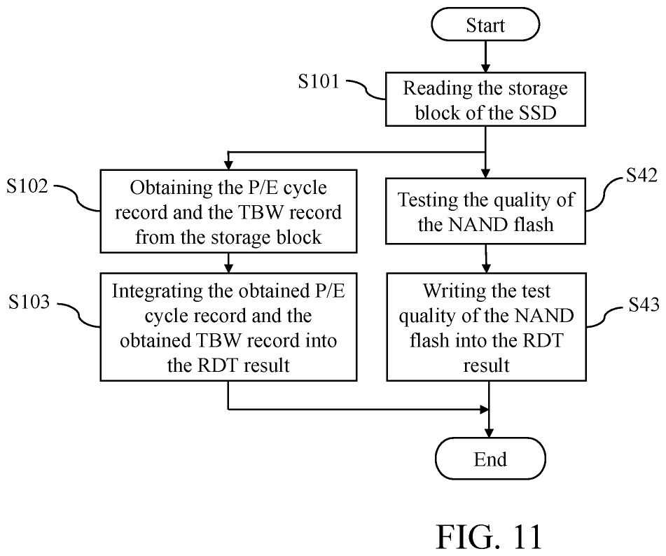

FIG. 10 is a flowchart of the RDT firmware generating the RDT result in a low-level formatting method of a storage device according to an embodiment of the present disclosure. First, the RDT firmware reads the storage block of the storage device (step S101). Then, the RDT firmware obtains the P/E cycle record and the TBW record from the storage block (step S102). Finally, the RDT firmware integrates the obtained P/E cycle record and the obtained TBW record into the RDT result (step S103). Similarly, the flowchart of FIG. 10 of the present disclosure is modified from the conventional flowchart of FIG. 4, and the details are shown in FIG. 11. That is, the steps S102 and S103 are executed in parallel to the conventional steps of “testing the quality of the NAND flash” and “writing the test quality of the NAND flash into the RDT result”. Accordingly, the RDT firmware can simultaneously perform steps S102 and S103 while performing the above conventional steps, so as to simultaneously integrate the information of the number of P/E cycles and the TBW, and the test quality of the NAND flash into the RDT result. When performing the low-level format method is required, the low-level formatting method of FIG. 7 is used to perform low-level format on the SSD according to the RDT result. Therefore, the process of integrating the obtained P/E cycle record and the obtained TBW record in the embodiment of the present disclosure does not affect the execution of the above exist steps at all, and therefore does not increase any cost. Without a doubt, it must be noted that the low-level formatting method in FIG. 7 only inherits the information of the number of P/E cycles and the TBW. After the flowchart in FIG. 7 ends, the conventional formatting program is performed (that is, the steps of “checking the damaged blocks of the NAND flash”, “calibrating the data to select the pulse phase”, and “writing the updated firmware to the NAND flash” in FIG. 6), so that the entire low-level formatting process of the SSD is completed.

In summary, only some steps (S82 and S83) are added to the conventional process of FIG. 5 in the low-level formatting method of the embodiment of the present disclosure, and the firmware storage information can be generated in synchronization with the conventional steps, and then the low-level formatting firmware further performs low-level format according to the firmware storage information, so that the inheritance of important information parameters during the low-level formatting can be realized without increasing the cost. Similarly, only some steps (S102 and S103) are added to the conventional process of FIG. 4 in the low-level formatting method of the present disclosure, and the RDT result can be generated in synchronization with the conventional steps, and then the low-level formatting firmware further performs low-level formatting according to the RDT result, so that the inheritance of important information parameters during the low-level formatting can be realized without increasing the cost.

Accordingly, the low-level formatting method of the embodiment of the present disclosure can indeed faithfully reflect the number of P/E cycles, the TBW and other information during the entire lifetime of the SSD. In addition to avoiding misjudging the lifetime of the SSD and irreversible data loss, the low-level formatting method of the embodiment of the present disclosure can also be applied to the RMA disk, so that when the returned disk is repaired, the true usage of the SSD can be inquired as a basis for providing product warranty.

In addition, the present disclosure also discloses a storage device. The storage device includes a processor and a plurality of storage blocks, and the processor executes the low-level formatting method.

Some or all of the aforementioned embodiments of the method of the present disclosure may be implemented in a computer program such as an operating system for a computer, a driver for a dedicated hardware of a computer, or a software application program. Other types of programs may also be suitable, as previously explained. Since the implementation of the various embodiments of the present invention into a computer program can be achieved by the skilled person using his routine skills, such an implementation will not be discussed for reasons of brevity. The computer program implementing some or more embodiments of the method of the present disclosure may be stored on a suitable computer-readable data carrier such as a DVD, CD-ROM, USB stick, a hard disk, which may be located in a network server accessible via a network such as the Internet, or any other suitable carrier.

Although the above-described elements are included in the drawings of the present disclosure, it should be noted that additional elements may be included to achieve better performance without departing from the spirit of the invention. Although each flowchart of the present disclosure is executed in a specified order, those skilled in the art can modify the order of these steps under the premise of achieving the same effect without violating the spirit of the invention. Therefore, the present disclosure is not limited to using only the sequence described above. In addition, those skilled in the art may also integrate several steps into one step, or perform more steps serially or in parallel, and the present disclosure is not limited thereto.

While the present disclosure has been described by way of example and in terms of the preferred embodiments, it should be understood that the present disclosure is not limited to the disclosed embodiments. On the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. A low-level formatting method for a storage device, the storage device having a plurality of storage blocks, the low-level formatting method comprising:
searching whether a reliability and duration test (RDT) result or firmware storage information is stored in the plurality of storage blocks, wherein at least one of the RDT result and the firmware storage information comprise a program-erase cycle (P/E cycle) record and a terabyte written (TBW) record of the storage device;
determining whether a number of P/E cycles and a TBW of the storage device are recorded in the P/E cycle record and the TBW record if at least one of the RDT result and the firmware storage information is stored in the plurality of storage blocks of the storage device;
writing default values of P/E cycles and the TBW of the storage device into one of the plurality of storage blocks of the storage device if the RDT result and the firmware storage information are not stored in the storage blocks of the storage device; and
writing values of the recorded number of P/E cycles and the recorded TBW of the storage device into one of the plurality of storage blocks of the storage device if the P/E cycles and the TBW of the storage device are recorded in the P/E cycle record and the TBW record.

2. The low-level formatting method according to claim 1, further comprising:
writing the default values of the P/E cycles and the TBW of the storage device into one of the plurality of storage blocks of the storage device if the P/E cycles and the TBW of the storage device are not recorded in the P/E cycle record and the TBW record.

3. The low-level formatting method according to claim 1, further comprising:
confirming validity of the P/E cycle record and the TBW record.

4. The low-level formatting method according to claim 1, further comprising:
reading one of the plurality of storage blocks of the storage device;
obtaining the P/E cycle record and the TBW record from the one of the plurality of storage blocks of the storage device; and
integrating the obtained P/E cycle record and the obtained TBW record into the RDT result.

5. The low-level formatting method according to claim 4, wherein in the process of obtaining and writing the P/E cycle record and the TBW record, the low-level formatting method further comprises:
testing the plurality of storage blocks of the storage device; and
writing test results of the plurality of storage blocks into the RDT result.

6. The low-level formatting method according to claim 5, wherein the test results of the plurality of storage blocks, the P/E cycle record, and the TBW record are integrated into the RDT result.

7. The low-level formatting method according to claim 1, wherein the P/E cycle record and the TBW record of the storage device at different time points are stored in the plurality of storage blocks of the storage device, and the low-level formatting method further comprises:
reading one of the plurality of storage blocks of the storage device;
obtaining the P/E cycle record and the TBW record of the storage device at the latest time point; and
writing the obtained P/E cycle record and the obtained TBW record back to a predetermined storage block of the plurality of storage blocks of the storage device to generate the firmware storage information.

8. The low-level formatting method according to claim 1, wherein the storage device is a flash memory device.

9. A storage device, which comprises a processor, which executes a low-level formatting method, and a plurality of storage blocks, the low-level formatting method comprising:
searching whether an RDT result or firmware storage information is stored in the plurality of storage blocks of the storage device, wherein at least one of the RDT result and the firmware storage information comprises a P/E cycle record and a TBW record of the storage device;
determining whether a number of P/E cycles and a TBW of the storage device are recorded in the P/E cycle record and the TBW record if at least one of the RDT result and the firmware storage information is stored in the plurality of storage blocks of the storage device;
writing default values of P/E cycles and the TBW of the storage device into one of the plurality of storage blocks of the storage device if the RDT result and the firmware storage information are not stored in the plurality of storage blocks of the storage device; and
writing values of the recorded number of P/E cycles and the recorded TBW of the storage device into one of the plurality of storage blocks of the storage device if the P/E cycles and the TBW of the storage device are recorded in the P/E cycle record and the TBW record.

10. The storage device according to claim 9, further comprising:
writing the default values of the P/E cycles and the TBW of the storage device into one of the plurality of storage blocks of the storage device if the P/E cycles and the TBW of the storage device are not recorded in the P/E cycle record and the TBW record.

11. The storage device according to claim 9, wherein the low-level formatting method further comprises:
confirming validity of the P/E cycle record and the TBW record.

12. The storage device according to claim 9, further comprising:
reading one of the plurality of storage blocks of the storage device;
obtaining the P/E cycle record and the TBW record from the one of the plurality of storage blocks of the storage device; and
integrating the obtained P/E cycle record and the obtained TBW record into the RDT result.

13. The storage device according to claim 12, wherein in the process of obtaining and writing the P/E cycle record and the TBW record, the low-level formatting method further comprises:
testing the plurality of storage blocks of the storage device; and
writing test results of the plurality of storage blocks into the RDT result.

14. The storage device according to claim 13, wherein test results of the plurality of storage blocks, the P/E cycle record, and the TBW record are integrated into the RDT result.

15. The storage device according to claim 9, wherein the P/E cycle record and the TBW record of the storage device at different time points are stored in the plurality of storage blocks of the storage device, and the low-level formatting method further comprises:
reading one of the plurality of storage blocks of the storage device;
obtaining the P/E cycle record and the TBW record of the storage device at the latest time point; and
writing the obtained P/E cycle record and the obtained TBW record back to a predetermined storage block of the plurality of storage blocks of the storage device to generate the firmware storage information.

16. The storage device according to claim 9, wherein the storage device is a flash memory device.
